(19) United States
(12) Patent Application Publication
(10) Pub. No.: US 2025/0261408 A1
(43) Pub. Date: Aug. 14, 2025

(54) LAYERED THIN FILM MATERIALS FOR TRANSISTOR CHANNELS

(71) Applicant: Intel Corporation, Santa Clara, CA (US)

(72) Inventors: Abhishek A. Sharma, Portland, OR (US); Sudipto Naskar, Portland, OR (US); Van H. Le, Beaverton, OR (US); Jin Jimmy Wang, Castro Valley, CA (US); Weimin Han, Portland, OR (US)

(73) Assignee: Intel Corporation, Santa Clara, CA (US)

(21) Appl. No.: 18/437,566

(22) Filed: Feb. 9, 2024

(51) Int. Cl. H01L 29/786; H01L 29/417; H01L 29/66

(52) U.S. Cl. CPC H10D 30/6757; H10D 30/6729; H10D 30/6755; H10D 99/00

(57) ABSTRACT

A thin-film transistor has a channel region with multiple thin-film layers. The transistor has a gate at one side (e.g., at the bottom) and two source/drain contacts on the opposite side (e.g., at the top). One or more channel layers closer to the gate (e.g., lower channel layers) have a higher mobility than one or more channel layers farther from the gate (e.g., upper channel layers). Reducing mobility near the top of the device increases stability of the channel during additional processing.

### BACKGROUND

Conventional transistors have a channel extending between a source region and a drain region, and a gate over the channel to turn the transistor on or off. The source region and drain region are each coupled to a respective contact that applies a current to the region. Similarly, the gate is connected to a contact to apply a current to the gate. Interconnect layers over a layer of transistors provide electrical connections to the transistors and to external devices and/or power supplies. In some IC designs, interconnect layers may be formed on both sides of the transistors, e.g., on a front side and a back side. For example, in some devices, the gate and gate contact may be moved to the back side of the device.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-section across a first embodiment of a transistor with a multi-layer channel, according to some embodiments of the present disclosure.

FIG. 2 is a cross-section of a second embodiment of a transistor with a multi-layer channel, with contacts extending into an upper layer of the channel, according to some embodiments of the present disclosure.

FIG. 3 is a cross-section of a third embodiment of a transistor with a multi-layer channel, with contacts extending into a lower layer of the channel, according to some embodiments of the present disclosure.

FIG. 4 is a cross-section of a fourth embodiment of a transistor with a multi-layer channel, with passivation layers between a pair of contacts, according to some embodiments of the present disclosure.

FIG. 5 is a flow diagram illustrating a process for fabricating a transistor with a multi-layered channel with higher mobility material near the gate, according to some embodiments of the present disclosure.

FIG. 6 is a flow diagram illustrating a process for fabricating a transistor with a multi-layered channel with higher concentrations of dielectric material further from the gate, according to some embodiments of the present disclosure.

FIG. 7 is a flow diagram illustrating a process for fabricating a transistor with a multi-layered channel with different carrier types in different layers of the channel, according to some embodiments of the present disclosure.

FIG. 8 is a flow diagram illustrating a process for fabricating a transistor with a multi-layered channel where the process includes a gas treatment on an upper layer of the channel, according to some embodiments of the present disclosure.

FIG. 9 is a flow diagram illustrating a process for fabricating a transistor with a multi-layered channel where the process includes a gas treatment on a lower layer of the channel, according to some embodiments of the present disclosure.

FIG. 10 is a cross-section of a transistor with a front-side gate and back-side source and drain contacts that may include a multi-layered channel, according to some embodiments of the present disclosure.

FIG. 11 is a perspective view of an example transistor implemented as a FinFET that may include a multi-layered fin-shaped channel, according to some embodiments of the present disclosure.

FIGS. 12A and 12B are top views of a wafer and dies that include one or more transistors with layered channel material accordance with any of the embodiments disclosed herein.

FIG. 13 is a cross-sectional side view of an IC device that may include one or more transistors with layered channel material in accordance with any of the embodiments disclosed herein.

FIG. 14 is a cross-sectional side view of an IC device assembly that may include one or more transistors with layered channel material in accordance with any of the embodiments disclosed herein.

FIG. 15 is a block diagram of an example computing device that may include one or more transistors with layered channel material in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

In general, a field-effect transistor (FET), e.g., a metal-oxide-semiconductor (MOS) FET (MOSFET), is a three-terminal device that includes source, drain, and gate terminals and uses electric field to control current flowing through the device. A FET typically includes a channel material, a source region and a drain region provided in the channel material, and a gate stack that includes a gate electrode material, alternatively referred to as a “work function” material, provided over a portion of the channel material between the source and the drain regions, and, optionally, also includes a gate dielectric material between the gate electrode material and the channel material.

Conventional FETs are controlled using a source contact that is coupled to the source region, a gate contact that is coupled to the gate stack, and a drain contact that is coupled to the drain region. Each contact can apply a voltage to the respective region, e.g., the source contact applies a voltage to the source region, and the gate contact applies a voltage to the gate stack. Various arrangements for the source, gate, drain, and contacts have been realized. Traditionally, the source, gate, and drain contacts are along a single side of the device (e.g., each are arranged over the channel material). In some arrangements, devices may have both front- and back-side contacts; for example, the source and drain regions, and the source and drain contacts, are on the front-side of the device, while the gate is on the back-side of the device. This can reduce the surface area needed for a each transistor, open up routing on both the front and back side of the transistor, improve device performance and reliability (e.g., by increasing the amount of surface area available for contacts and thus reducing the rate of shorts between adjacent contacts), and provides other benefits.

One particular type of transistor is a thin-film transistor (TFT). A TFT is a special kind of a FET that is made by depositing a thin film of an active semiconductor material over a supporting layer that may be a non-conducting layer. Additional thin films may be deposited for additional features, e.g., to form a gate conductor, gate dielectric, contacts, etc. TFTs typically include a thin film of a high-mobility semiconductor material to form the channel region. For example, high-mobility materials include tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide.

The high-mobility materials used for TFTs may be prone to defects, e.g., during later processing stages that expose the channel material to high temperatures and/or other detrimental conditions; defects in the channel region can lead to reduced gate control. In some cases, a passivation layer over the channel can help protect the TFT from processing impacts; however, in some cases, the deposition process of the passivation layer itself may have performance impacts on the channel.

As described herein, a transistor such as a TFT may have a multi-layered channel region, with one or more higher-mobility layers nearer to the gate, and one or more lower-mobility layers nearer to the source and drain contacts. For example, a gate may be on the back-side of the transistor, with a channel region over the gate. The channel region may include a higher-mobility layer directly over the gate or the gate oxide, and a lower-mobility layer over the higher-mobility layer. Source and drain contacts may extend at least partially into the lower-mobility layer, and in some cases, into the higher-mobility layer. More generally, the channel region may include a stack of multiple channel layers, with higher-mobility layers near the bottom of the stack (i.e., nearer to the gate), and lower-mobility layers near the top of the stack (i.e., farther from the gate).

Different materials and/or processes may be used to form the multi-layered channels. In some embodiments, higher mobility materials are included near the gate. For example, high-mobility oxides, such as indium oxide, tin oxide, cobalt oxide, and/or copper oxide, are included in layers closer to the gate, or included at higher concentrations in a layer nearer to the gate than in a layer farther from the gate. In some embodiments, low-mobility or insulating materials, such as insulating oxides or nitrides, are included in a layer at or near the top of the channel. In some embodiments, heat treatments, gas treatments, or other types of treatments are applied to either increase mobility within a layer (e.g., in a layer nearer to the gate), or to increase stability of a layer (e.g., of the upper layer). In some embodiments, different carrier types are used at different parts of the channel stack; for example, the lower channel layers may be an n-type semiconductor, while an upper layer has is a p-type semiconductor. In some cases, two or more techniques for increasing mobility near the gate and/or increasing stability farther away from the gate are used in combination.

The transistors with layered channel material described herein may be implemented in, or in combination with, more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

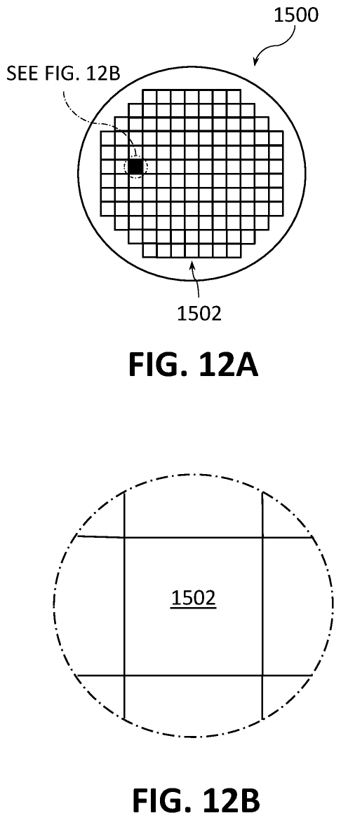

For convenience, if a collection of drawings designated with different letters are present, e.g., FIGS. 12A-12B, such a collection may be referred to herein without the letters, e.g., as “FIG. 12.”

### Example Transistors with Multi-Layered Channel

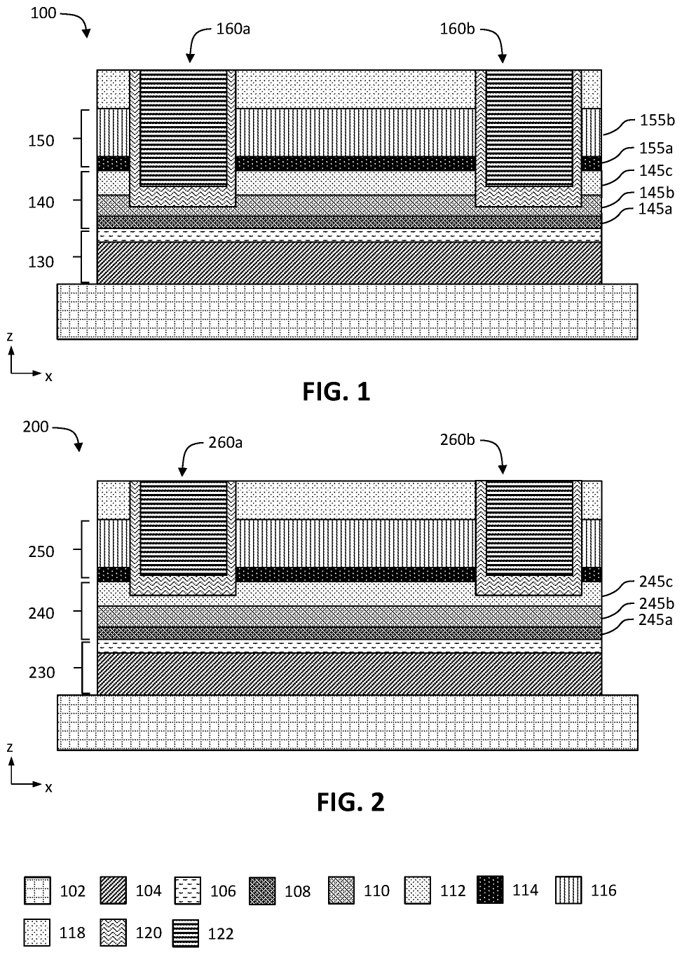

FIGS. 1-4 illustrate four example embodiments of a transistor with a multi-layer channel. Each of FIGS. 1-4 is a cross-section across a respective transistor, showing the channel, source, gate, and drain. A number of elements referred to in the description of FIGS. 1-4 and with reference numerals are illustrated in these figures with different patterns, with a legend at the bottom of the page showing the correspondence between the reference numerals and patterns. The legend illustrates that FIGS. 1-4 use different patterns to show a support structure 102, a gate electrode 104, a gate dielectric 106, a first channel material 108, a second channel material 110, a third channel material 112, a first passivation material 114, a second passivation material 116, a dielectric material 118, a first contact material 120, and a second contact material 122.

In the drawings, some example structures of various devices and assemblies described herein are shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

In general, implementations of the present disclosure may be formed or carried out on a substrate, e.g., the support structure 102 illustrated in FIG. 1. The support structure 102 may be, e.g., a substrate, a die, a wafer or a chip. For example, the support structure may be the wafer 1500 of FIG. 12A, discussed below, and may be, or be included in, a die, e.g., the singulated die 1502 of FIG. 12B, discussed below. The support structure 102 extends along the x-y plane in the coordinate system shown in FIG. 1. In some embodiments, a support structure 102 may be used during a fabrication process and later removed. For example, a top side of the transistor 100 may be attached to a second support structure (e.g., a second one of the support structures 102, which may be referred to as a carrier structure), and at least a portion of the support structure 102 over which the transistor 100 is formed may be removed to expose the back side of the transistor 100. This may enable electrical connections to the gate electrode 104, e.g., back-side contacts and one or more back-side metal layers forming a metallization stack.

In some embodiments, the support structure 102 may be a substrate that includes silicon and/or hafnium. More generally, the support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the substrate may be formed are described here, any material that may serve as a foundation upon which a semiconductor device including one or more nanoribbon transistors, as described herein, may be built falls within the spirit and scope of the present disclosure.

In each of FIGS. 1-4, a transistor 100, 200, 300, or 400 is formed over a support structure 102. Turning first to FIG. 1, the transistor 100 includes a gate stack 130, a channel region 140, a passivation region 150, and a pair of source or drain contacts 160a and 160b.

In this example, the gate stack 130 includes a gate electrode 104 and gate dielectric 106. One or both of the gate electrode 104 and gate dielectric 106 may be deposited as thin films. Transistors often include a gate dielectric between the gate electrode 104 and the channel material, e.g., the channel region 140. While not specifically shown, in some embodiments, the gate electrode 104 includes multiple layers, e.g., layers of different conductive materials. Furthermore, in some embodiments, the gate dielectric 106 includes multiple layers, e.g., an oxide layer and a high-k dielectric layer. In some embodiments, the gate dielectric 106 may be omitted.

The gate electrode 104 includes a conductive material, such as a metal. The gate electrode 104 may include at least one P-type work function metal or N-type work function metal, depending on whether the transistor 100 is a PMOS transistor or an NMOS transistor. For a PMOS transistor, metals that may be used for the gate electrode 104 may include, but are not limited to, ruthenium, palladium, platinum, cobalt, nickel, and conductive metal oxides (e.g., ruthenium oxide). For an NMOS transistor, metals that may be used for the gate electrode 104 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). As noted above, in some embodiments, the gate electrode 104 may include a stack of two or more metal layers, where one or more metal layers are work function metal layers and at least one metal layer is a fill metal layer.

In various embodiments, the gate dielectric 106 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, the gate dielectric 106 may have a thickness between about 0.5 nanometers and 3 nanometers, including all values and ranges therein, e.g., between about 1 and 3 nanometers, or between about 1 and 2 nanometers.

In this example, the channel region 140 includes three layers 145a, 145b, and 145c, referred to collectively as channel layers 145 or individually as channel layer 145. Each channel layer 145 is at a different height in the z-direction in the orientation shown in FIG. 1, i.e., a different distance from the support structure 102, and a different distance from the gate stack 130, where the channel layer 145a is the lower-most layer at the shortest distance from the support structure 102 and the gate stack 130, and the channel layer 145c is the upper-most layer at the farthest distance from the support structure 102 and the gate stack 130. In other examples, the channel region 140 may include more or fewer layers, e.g., two, four, five, six or more layers of the same or different channel materials.

The first channel layer 145a includes the first channel material 108. The second channel layer 145b includes the second channel material 110. The third channel layer 145c includes the third channel material 112. In some embodiments, one or more layers (e.g., layers 145a and 145b) may include the same channel material (e.g., the first channel material 108).

In general, the first channel material 108 at the bottom of the channel region 140 and nearest to the gate stack 130 is a relatively high-mobility material. For example, the first channel material 108 may have a higher carrier mobility (i.e., electron and/or hole mobility) than silicon. In various embodiments, the first channel material 108 may include a high mobility oxide semiconductor material, such as tin oxide, antimony oxide, indium oxide, indium tin oxide (ITO), titanium oxide, zinc oxide, indium zinc oxide, indium gallium zinc oxide (IGZO), gallium oxide, titanium oxynitride, ruthenium oxide, tungsten oxide, or indium tungsten oxide. In other embodiments, the first channel material 108 may include cobalt oxide, copper oxide (e.g., Cu₂O or CuO), ruthenium oxide, titanium oxynitride, nickel oxide, niobium oxide, copper peroxide, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus. The first channel material 108 may be doped with one or more of gallium, indium, aluminum, fluorine, boron, phosphorus, arsenic, nitrogen, tantalum, tungsten, and magnesium, etc.

In certain embodiments, the first channel material 108 includes oxygen and a metal, e.g., oxygen and indium, copper, cobalt, and/or tin. The oxygen and the metal(s) may form a high mobility oxide described above (e.g., indium oxide, copper oxide, cobalt oxide, and/or tin oxide). In some embodiments, the bulk of the first channel layer 145a may include one material (e.g., IGZO), and the first channel layer 145a further includes an additional high-mobility material (e.g., tin oxide) interspersed in the bulk material. Both materials (the bulk semiconductor and the additional high-mobility material) may be high-mobility, and the additional material may increase the mobility of the first channel layer 145a. In other examples, different metals or metal oxides may be added, e.g., zinc, tungsten, etc. In some embodiments, multiple metals (e.g., copper and tin) may be added to the first channel layer 145a.

In some embodiments, a high mobility in the first channel layer 145a is achieved by a gas treatment or other processing (e.g., exposure to vacuum environment, exposure to high ambient temperature) during and/or after deposition of the first channel layer 145a. For example, a gas and/or heat treatment (e.g., between 250° C. and 400° C.) may heal dangling bonds within the first channel layer 145a or otherwise change configurations of the first channel material 108 at an atomic level. In some cases, a gas in the chamber during a gas treatment may be introduced into the first channel layer 145a and may be detectable in the first channel layer 145a. For example, the first channel layer 145a may include nitrogen, sulfur, fluorine, hydrogen, or deuterium, which may suggest that a gas treatment was performed on the first channel layer 145a.

The second channel material 110 may include any of the materials described with respect to the first channel material 108. In some embodiments, the second channel material 110 is selected from the same materials described with respect to the first channel material 108, but the second channel material 110 has a lower carrier mobility and/or lower conductivity than the first channel material 108. In some embodiments, the second channel material 110 may have a similar but slightly different composition. For example, the second channel material 110 may have a lower concentration of a dopant than the first channel material 108. As another example, the first channel layer 145a and second channel layer 145b may include different concentrations of a high-mobility additive, e.g., the first channel layer 145a may have a higher concentration of indium oxide, tin oxide, cobalt oxide, or copper oxide than the second channel layer 145b. This may be detected as a higher concentration of the metal (e.g., indium, tin, cobalt, or copper) in the first channel layer 145a than in the second channel layer 145b. A gas treatment may be performed on the second channel layer 145b, e.g., during or following deposition of the second channel material 110.

The third channel material 112 in the third channel layer 145c, which is at the top of the channel region 140 and farthest from the gate stack 130, may be a relatively low-mobility material. In some embodiments, the third channel material 112 has a carrier mobility that is lower than the carrier mobility of the first channel material 108. The third channel material 112 may also have a carrier mobility that is lower than the carrier mobility of the second channel material 110. In some embodiments, the third channel material 112 may have a lower carrier mobility than silicon or a lower carrier mobility than germanium.

The third channel material 112 may generally include any of the materials described above with respect to the first channel material 108. The third channel material 112 may include a lower concentration of one or more high-mobility materials than the first channel material 108 and/or the second channel material 110. For example, if the first channel material 108 includes an oxygen and a metal (e.g., indium, copper, cobalt, or tin) forming a high-mobility oxide within the first channel layer 145a, the third channel material 112 may include a lower concentration of the metal (e.g., a lower concentration of indium, tin, cobalt, or copper), or the third channel material 112 may not include the metal, or only trace amounts of the metal. For example, the third channel material 112 may include less than 0.1%, less than 0.05%, less than 0.01%, or less than 0.001% of the metal by weight.

As another example, if a gas treatment, heat treatment, or other sort of processing or post-processing treatment to increase mobility was applied to the first channel material 108, the third channel material 112 may not have had a similar treatment. In this case, the third channel material 112 may not include a material (e.g., nitrogen, sulfur, fluorine, hydrogen, or deuterium) indicating that a treatment was applied, or may include a lower concentration of this material.

In some embodiments, additional materials are added to the third channel material 112 to reduce carrier mobility and/or increase material stability. In some embodiments, the third channel material 112 may include at least one non-metal element to increase stability of the third channel layer 145c. In particular, the third channel material 112 may include the non-metal at a higher concentration than the first channel material 108 and/or the second channel material 110. For example, the third channel material 112 may include one or more of nitrogen, oxygen, sulfur, selenium, phosphorus, hydrogen, and deuterium at a higher concentration than the first channel material 108 and/or the second channel material 110. This may result in the third channel material 112 having a higher bandgap than the first channel material 108 and/or second channel material 110. In addition, the third channel material 112 may have a lower rate of defects (e.g., number of defects observed in a particular volume, cross-sectional area, or set of cross-sectional areas) than the first channel material 108 and/or second channel material 110.

As another example, the third channel material 112 may include one or more insulating oxides or nitrides to reduce mobility and/or increase stability of the third channel layer 145c. The third channel material 112 includes these insulating materials in addition to a semiconductor material, e.g., any of the high-mobility semiconductor materials (e.g., a semiconducting oxide) described above. For example, the third channel material 112 may include a metal that, when combined with oxygen or nitrogen, forms an insulator; the third channel material 112 may also include oxygen or nitrogen for forming the insulator. Example metals that may be included in the third channel material 112 include aluminum (e.g., in the form of aluminum oxide or aluminum nitride), hafnium (e.g., in the form of aluminum oxide), tungsten (e.g., in the form of tungsten oxide), magnesium (e.g., in the form of magnesium oxide), gallium (e.g., in the form of gallium nitride). This may result in the third channel material 112 having a higher bandgap than the first channel material 108 and/or second channel material 110.

While the insulating materials (e.g., non-metals and insulating oxides or nitrides) are described as being included in the third channel material 112 of the upper-most channel layer 145c, in some embodiments, one of or multiple of these insulating materials may be included in one or more lower layers, e.g., the first channel layer 145a and/or second channel layer 145b. The concentration of an insulating material or component of an insulating material (e.g., one of the metals that forms an insulating oxide, or one of the non-metal elements) in the third channel layer 145c may be greater than the concentration of the insulating material or component in the lower channel layers 145a and 145b.

In some embodiments, the first channel layer 145a and third channel layer 145c may have different charge carrier types. In conductor and semiconductor materials, a charge carrier is a particle or quasiparticle that can move within the material, carrying a conductive charge and resulting in a net motion of particles through the material. In some semiconductors, the main charge carriers are electrons, while in others, the main charge carriers are electron holes (i.e., electron vacancies), generally referred to as holes. A semiconductor material or semiconductor region with holes is referred to as p-type, and a semiconductor material or semiconductor region with electrons is referred to as n-type. Doping may be used to create a p-type or n-type material; for example, silicon can be doped such that it is either n-type or p-type. Having an opposite charge carrier on one or more upper layers (e.g., the third channel layer 145c) compared to the rest of the channel region 140 (e.g., the first channel layer 145a and second channel layer 145b) can improve stability of the upper layer(s), e.g., by reducing current leakage in the transistor 100 while it is in the off state.

In some embodiments, the third channel material 112 is a p-type semiconductor material with electron holes, while the first channel material 108 and, in some cases, the second channel material 110 is an n-type semiconductor material with electrons. Alternatively, the third channel material 112 is an n-type semiconductor material with electrons, while the first channel material 108 and, in some cases, the second channel material 110 is a p-type semiconductor material with electron holes.

In some embodiments, each of the first channel material 108 and third channel material 112 include a particular metal and oxygen, where the amount of oxygen relative to the metal determines the carrier type. For example, the metal may be tin (Sn), which can form SnO₂, which is an n-type material, and SnO₍₂₋ₓ₎, with x>0 and x<1.5, which is a p-type material. As another example, the metal may be copper, which can form CuO₂, which is an n-type material, and CuO, which is a p-type material. Thus, different oxygen concentrations in combination with the metal indicate the layering of n-type and p-type materials. In other examples, different combinations of materials may be used to produce a channel region with a p-type layer and an n-type layer. If there are three or more channel layers, one or more middle layers (e.g., the second channel layer 145b) may have a same carrier type as either the uppermost layer 145c or the lowermost layer 145a. For example, the second channel layer 145b may have the same carrier type as the first channel layer 145a, but the second channel layer 145b may have a lower concentration of the charge carrier than the first channel layer 145a; in other words, the first channel layer 145a may be the most highly doped, while the second channel layer 145b is less highly doped.

In some cases, the relative mobilities of the channel materials 108, 110, and/or 112 may be observed or inferred through testing. For example, a radiography or x-ray test may be performed on the channel materials to assess their mobility or conductivity. A higher observed diffraction response may indicate that a particular material (e.g., the first channel material 108) has a higher conductivity or mobility than another material (e.g., third channel material 112).

As noted above, one or more of the channel layers 145 may be a thin film. In some embodiments, one or more of the channel layers 145 may have a thickness between about 5 and 75 nanometers, including all values and ranges therein. In some embodiments, one or more channel layers 145 have a thickness that is below 40 nanometers, below 30 nanometers, below 25 nanometers, below 20 nanometers, below 15 nanometers, below 10 nanometers, below 5 nanometers, or below 3 nanometers. In some embodiments, one or more channel layers 145 may have a monolayer thickness. A monolayer is a single layer of atoms or molecules. For example, a monolayer of a particular crystal material may have a thickness equal to the unit height of the crystal structure. Different materials have different monolayer heights depending on the molecule size, atom size, or crystal size, for example.

The transistor 100 further includes a passivation region 150 that includes a first passivation layer 155a and a second passivation layer 155b, referred to jointly as passivation layers 155. While two passivation layers 155 are shown in FIG. 1, in other examples, the passivation region 150 may include a single passivation layer 155 or more than two passivation layers 155. The passivation layers 155 may provide protection to the underlying channel region 140, e.g., to protect the channel region 140 during additional fabrication processes. In some embodiments, the passivation layer 155a is created by a chemical reaction with the third channel layer 145c. Further passivation layers, e.g., the passivation layer 155b, may be created by a chemical reaction with a lower passivation layer, or by depositing an additional material over the lower passivation layer (e.g., the first passivation layer 155a).

In this example, the passivation layer 155a includes the first passivation material 114, and the passivation layer 155b includes the second passivation material 116. Individual passivation materials 114 and 116 may be selected for one or more properties, such as ability to form a hermetic seal over the channel region 140, ability to act as an etch stop during later processing steps, or ability to act as a hard mask in later processing steps (e.g., during formation of the contacts 160a and 160b). In some cases, a sealing passivation material may be selected to hermetically seal against oxygen and/or hydrogen. Oxygen or hydrogen may increase conductivity at the top of the channel region 140, which, as discussed above, can be undesirable. In some embodiments, a passivation layer 155 (e.g., the first passivation layer 155a) may induce a depletion layer at the interface with the channel region 140, e.g., at a top of the third channel layer 145c. In some embodiments, the first passivation layer 155a does not introduce doping or charge on the channel region 140.

In some embodiments, one or both of the passivation materials 114 and 116 may include aluminum, silicon, and/or yttrium, which, in combination with oxygen nitrogen, can provide a hermetic seal. In some embodiments, one or both of the passivation materials 114 and 116 may include an insulating oxide or insulating nitride, e.g., one or more metals (e.g., selected aluminum, titanium, tantalum, yttrium, zirconium, zinc) combined with oxygen or nitrogen, or a semiconductor (e.g., silicon, gallium) combined with oxygen or nitrogen.

A layer of dielectric material 118 is included over the passivation region 150. The dielectric material 118 may be an interlayer dielectric (ILD). The dielectric material 118 may include one or more low-k or high-k dielectrics including, but not limited to, elements such as hafnium, silicon, oxygen, nitrogen, titanium, tantalum, lanthanum, aluminum, zirconium, barium, strontium, yttrium, lead, scandium, niobium, and zinc. Further examples of dielectric materials include, but are not limited to silicon nitride, silicon oxide, silicon dioxide, silicon carbide, silicon nitride doped with carbon, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

Two contacts 160a and 160b, referred to jointly as contacts 160, are coupled to the channel region 140 of the transistor 100. In this example, each contact 160 includes a first contact material 120 forming a liner and a second contact material 122 forming a core. In other examples, the contacts 160 may include more layers, e.g., two or more liner layers and a core, or a single material. In some embodiments, the first contact material 120 is a high-mobility semiconductor material. For example, any of the materials described with respect to the first channel material 108 may be used as the first contact material 120, and any of the techniques for fabricating the first channel material 108 described above may be used to fabricate the first contact material 120. The second contact material 122 may be a more conductive material, e.g., a metal. In some embodiments, the second contact material 122 may include any of the materials described with respect to the gate electrode 104.

In the cross-section shown in FIG. 1, the contacts 160a and 160b extend through the dielectric material 118, through the passivation region 150, and into the channel region 140. In particular, the contacts 160 extend through the third channel layer 145c and partially through the second channel layer 145b, with the lower ends of the contacts 160 extending partway into the second channel layer 145b.

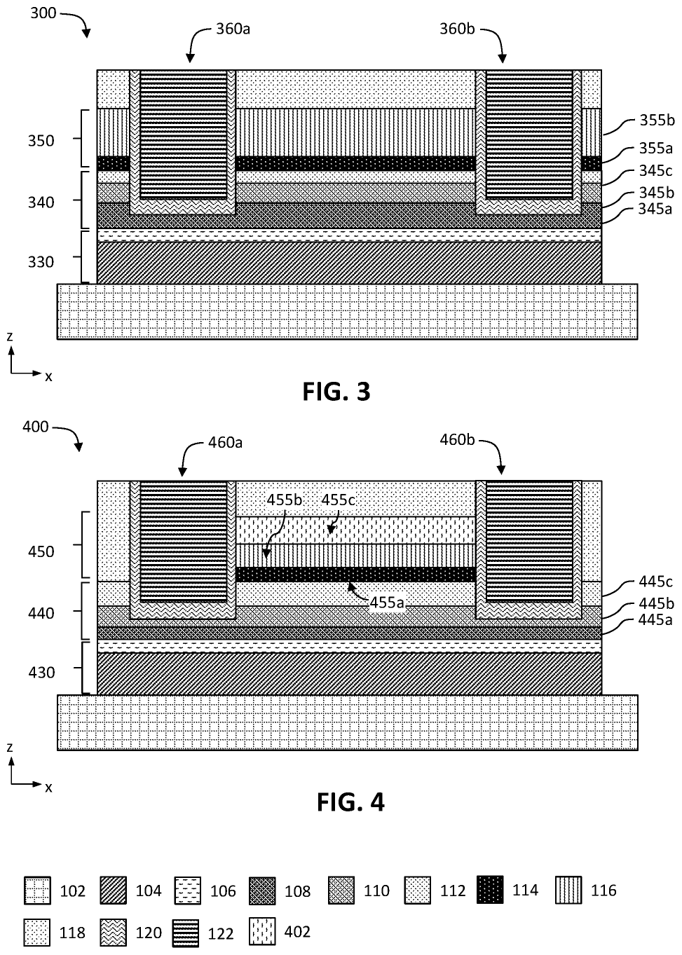

In other examples, the contacts 160 extend into a different layer of the channel region 140. FIGS. 2 and 3 illustrate alternate embodiments with contacts extending into different layers of the channel.

FIG. 2 is a cross-section of a second embodiment of a transistor with a multi-layer channel, with contacts extending into an upper layer of the channel, according to some embodiments of the present disclosure. FIG. 2 provides a transistor 200 that includes a gate stack 230, a channel region 240, a passivation region 250, and contacts 260a and 260b. The gate stack 230 is similar to the gate stack 130; the channel region 240 is similar to the channel region 140; and the passivation region 250 is similar to the passivation region 150. In FIG. 2, the contacts 260 extend through the dielectric material 118, through the passivation region 250, and into the upper channel layer 245c of the channel region 240. The contacts do not extend into the lower channel layers 245a and 245b.

FIG. 3 is a cross-section of a third embodiment of a transistor with a multi-layer channel, with contacts extending into a lower layer of the channel, according to some embodiments of the present disclosure. FIG. 3 provides a transistor 300 that includes a gate stack 330, a channel region 340, a passivation region 350, and contacts 360a and 360b. The gate stack 330 is similar to the gate stack 130 and the passivation region 350 is similar to the passivation region 150. The channel region 340 includes three channel layers 345a, 345b, and 345c; these may have any of the channel materials described with respect to the channel region 140 (e.g., the channel materials 108, 110, and 112), but the channel layers 345 are depicted as having different heights from the channel layers 145, e.g., with the channel layer 345a being thicker than the channel layer 145c, and the channel layer 345c being thinner than the channel layer 145a. In FIG. 3, the contacts 360 extend through the dielectric material 118, through the passivation region 350, through the channel layers 345c and 345b, and partially through the lower channel layer 345a. The contacts 360 do not reach the gate stack 330, which would lead to a short.

FIG. 4 is a cross-section of a fourth embodiment of a transistor with a multi-layer channel, with passivation layers between a pair of contacts, according to some embodiments of the present disclosure. FIG. 4 provides a transistor 400 that includes a gate stack 430, a channel region 440, a passivation region 450, and contacts 460a and 460b. The gate stack 430 is similar to the gate stack 130; the channel region 440 is similar to the channel region 140; and the contacts 460 are similar to the contacts 160. In this example, the passivation region 450 includes three passivation layers 455a, 455b, and 455c; these may each include any of the channel materials described with respect to the passivation region 150. In this example, the passivation layer 455a includes the first passivation material 114, the passivation layer 455b includes the second passivation material 116, and the passivation layer 455c includes a third passivation material 402. The third passivation material 402 may be any of the materials described with respect to the first passivation material 114 and second passivation material 116.

In the example of FIG. 4, the passivation layers 455 are located between the contacts 460a and 460b. On the opposite sides of the contacts (e.g., to the left of the contact 460a and to the right of the contact 460b), the dielectric material 118 is directly over the channel region 440.

### Example Processes for Forming Transistor Device with Layered Thin Film Channels

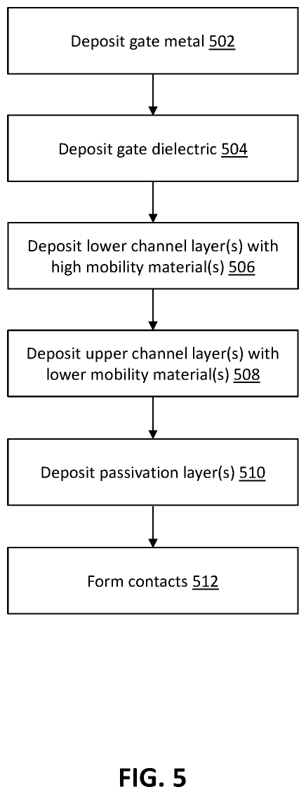

FIGS. 5-9 provide flow diagrams of processes for fabricating transistors with layered thin film channels, e.g., the transistors 100-400 shown in FIGS. 1-4. In general, the processing methods illustrated in FIGS. 5-9 can be performed across a wafer or die, with many individual transistors formed on the wafer or die. Additional steps may be performed before, during, and/or after any of the processes shown in FIGS. 5-9 to produce an integrated circuit device that includes the layered channel materials described herein. Furthermore, processing steps or aspects of FIGS. 5-9 may be combined to generate the transistor devices described above.

FIG. 5 is a flow diagram illustrating a process for fabricating a transistor with a multi-layered channel with higher mobility material near the gate, according to some embodiments of the present disclosure. At 502, a gate metal is deposited. For example, the gate electrode 104 is deposited as a thin film over a substrate, such as the support structure 102. The gate metal may be any of the conductive materials described with respect to the gate electrode 104; in some embodiments, the gate electrode is not a metal, or is a combination of one or more metals and one or more other materials.

At 504, a gate dielectric is deposited. For example, the gate dielectric 106 is deposited as a thin film over the gate electrode 104. The gate dielectric may be any of the dielectric materials described with respect to the gate dielectric 106. As noted above, in some embodiments, the gate dielectric may be omitted.

At 506, one or more lower channel layers that include high-mobility materials are deposited. For example, the first channel layer 145a is deposited as a thin film over the gate stack, e.g., over the gate dielectric. As described with respect to FIG. 1, the first channel layer 145a includes the first channel material 108, which may be a semiconductor material having a relatively high mobility, e.g., higher than other materials in the channel region. For example, one or more layers of channel material that includes indium, tin, cobalt, or copper may be deposited, as described with respect to FIG. 1. In some embodiments, multiple high mobility layers are deposited, e.g., the first channel layer 145a and the second channel layer 145b. In some embodiments, each layer may have the same mobility or a lower mobility than the prior layer that was deposited.

At 508, one or more upper channel layers that include lower mobility materials are deposited. For example, the third channel layer 145c is deposited as a thin film over one or more layers of higher mobility channel material, e.g., the first channel layer 145a and second channel layer 145b. As described with respect to FIG. 1, the third channel layer 145c includes the third channel material 112, which may be a semiconductor material having a relatively low mobility, e.g., lower than other materials in the channel region. For example, one or more layers of channel material that includes a non-metal combined with a semiconductor material, or an insulating oxide combined with a semiconductor material, may be deposited, as described with respect to FIG. 1. In some embodiments, multiple lower mobility layers are deposited, e.g., the second channel layer 145b and the third channel layer 145c.

At 510, one or more passivation layers are deposited. For example, the first passivation layer 155a and passivation layer 155b are deposited as thin films over the channel region 140, which includes the channel layers described above. The passivation layers may include the first passivation material 114 and/or second passivation material 116, which may provide one or more protective properties for the channel region, as described with respect to FIG. 1.

At 512, source and drain contacts are formed over the transistor. As illustrated in FIGS. 1-4, the source and drain contacts, e.g., the contacts 160, 260, 360, or 460, may extend into the channel region 140, 240, 340, or 440. The contacts may extend through one or more of the channel layers, e.g., into one or more of the lower mobility channel layers, and, optionally, into one or more of the higher mobility channel layers.

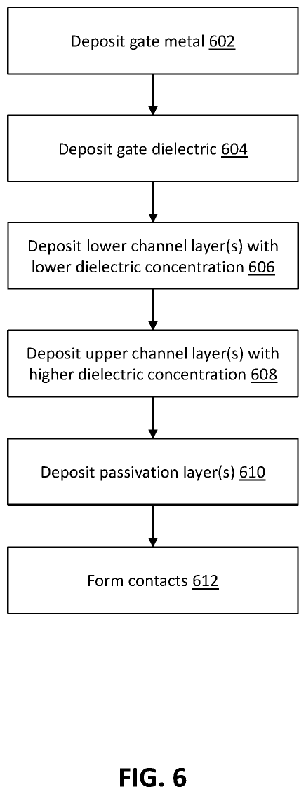

FIG. 6 is a flow diagram illustrating a process for fabricating a transistor with a multi-layered channel with higher concentrations of dielectric material further from the gate, according to some embodiments of the present disclosure. At 602, a gate metal is deposited, as described with respect to the process 502 of FIG. 5. At 604, a gate dielectric may be deposited, as described with respect to the process 504 of FIG. 5.

At 606, one or more lower channel layers that include a lower concentration of a dielectric material are deposited. For example, the first channel layer 145a is deposited as a thin film over the gate stack, e.g., over the gate dielectric. As described with respect to FIG. 1, the first channel layer 145a includes the first channel material 108, which may include a semiconductor (e.g., a high mobility semiconductor) along with a relatively low concentration of a dielectric material. The dielectric material may increase stability of a high mobility semiconductor material. For example, the dielectric material may be any of the insulating oxides, insulating nitrides, and/or non-metal materials described with respect to FIG. 1. In some embodiments, multiple lower channel layers are deposited, e.g., the first channel layer 145a and the second channel layer 145b. In some embodiments, each layer may have a greater concentration of the insulating material than the prior layer that was deposited.

At 608, one or more upper channel layers that include a higher concentration of the dielectric material are deposited. For example, the third channel layer 145c is deposited as a thin film over one or more layers with lower concentrations of the dielectric material, e.g., the first channel layer 145a and second channel layer 145b. As described with respect to FIG. 1, the third channel layer 145c includes the third channel material 112, which may be a semiconductor material having a higher concentration of the insulating oxide, insulating nitride, or non-metal material.

At 610, one or more passivation layers are deposited, as described with respect to the process 510 of FIG. 5. At 612, source and drain contacts are formed over the transistor, as described with respect to the process 512 of FIG. 5.

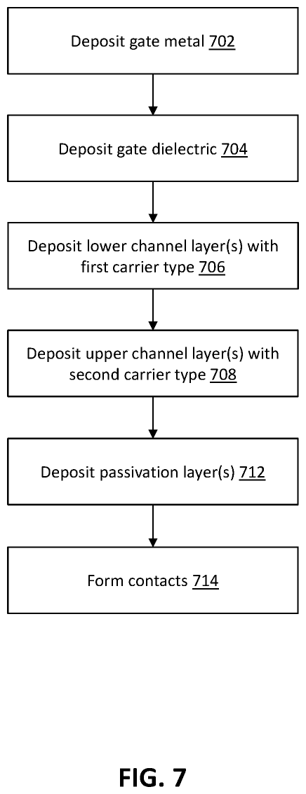

FIG. 7 is a flow diagram illustrating a process for fabricating a transistor with a multi-layered channel with different carrier types in different layers of the channel, according to some embodiments of the present disclosure. At 702, a gate metal is deposited, as described with respect to the process 502 of FIG. 5. At 704, a gate dielectric may be deposited, as described with respect to the process 504 of FIG. 5.

At 706, one or more lower channel layers that include a first carrier type are deposited. For example, the first channel layer 145a is deposited as a thin film over the gate stack, e.g., over the gate dielectric. As described with respect to FIG. 1, the first channel layer 145a includes the first channel material 108, which may include a semiconductor with a first carrier type, e.g., holes or electrons. The first channel layer 145a may have a relatively high carrier mobility; for example, any of the high-mobility channel materials described with respect to FIG. 1 may be deposited. In some embodiments, multiple lower channel layers are deposited, e.g., the first channel layer 145a and the second channel layer 145b. In some embodiments, each lower layer may have the same carrier type. In some embodiments, each layer has a lower concentration of the charge carrier than the prior layer that was deposited, such that the lowest layer (i.e., the layer closest to the gate) has the highest concentration of the charge carrier.

At 708, one or more upper channel layers that include a second carrier type are deposited. For example, a third channel layer 145c having the second carrier type is deposited as a thin film over one or more layers with the first carrier type, e.g., the first channel layer 145a and second channel layer 145b.

At 710, one or more passivation layers are deposited, as described with respect to the process 510 of FIG. 5. At 712, source and drain contacts are formed over the transistor, as described with respect to the process 512 of FIG. 5.

Any of the processes described with respect to FIGS. 5-7 may be combined. For example, a transistor may have a first channel layer 145a with a higher concentration of a high-mobility material than the third channel layer 145c (as described with respect to FIG. 5), and the third channel layer 145c may have a higher concentration of a dielectric material than the first channel layer 145a (as described with respect to FIG. 6). As another example, the third channel layer 145c may have both a dielectric material included therein (as described with respect to FIG. 6), as well as a semiconductor material with an opposite carrier type from the first and second channel layers 145a and 145b (as described with respect to FIG. 7).

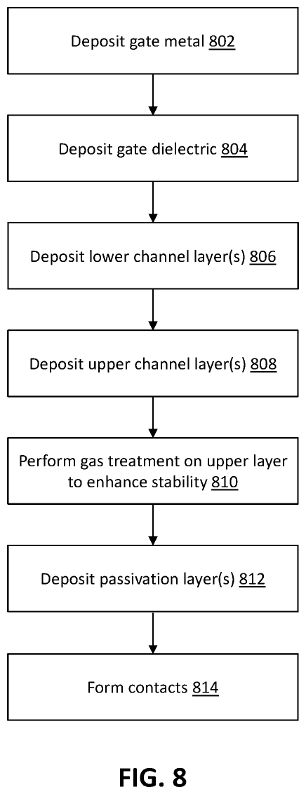

FIG. 8 is a flow diagram illustrating a process for fabricating a transistor with a multi-layered channel where the process includes a gas treatment on an upper layer of the channel, according to some embodiments of the present disclosure. At 802, a gate metal is deposited, as described with respect to the process 502 of FIG. 5. At 804, a gate dielectric may be deposited, as described with respect to the process 504 of FIG. 5.

At 806, one or more lower channel layers are deposited. For example, the channel materials 108 and 110 may be deposited as thin films to form the channel layers 145a and 145b. The lower channel material(s) may have any of the properties described with respect to FIGS. 1, 5, 6, and/or 7.

At 808, one or more upper channel layers are deposited. For example, the channel material 112 may deposited as a thin film to form the channel layer 145c. The upper channel material(s) may have any of the properties described with respect to FIGS. 1, 5, 6, and/or 7. In some embodiments, the upper channel material is the same as the lower channel material. For example, each of the lower channels and the upper channels may include a high mobility semiconductor.

At 810, a gas treatment is performed on the upper channel layer to enhance its stability. For example, a gas treatment may introduce or increase the concentration of a non-conductive element in the upper channel layer, leading to a higher concentration of, for example, nitrogen, oxygen, sulfur, selenium, phosphorus, hydrogen, or deuterium. As noted above, this may result in the upper channel layer having a higher bandgap than the lower channel layer(s). In addition, the upper channel layer may have a lower rate of defects than the lower channel layer(s). In some embodiments, the processes 808 and 810 may be performed in parallel, e.g., the gas may be introduced during deposition of the upper channel layer.

At 812, one or more passivation layers are deposited, as described with respect to the process 510 of FIG. 5. At 814, source and drain contacts are formed over the transistor, as described with respect to the process 512 of FIG. 5.

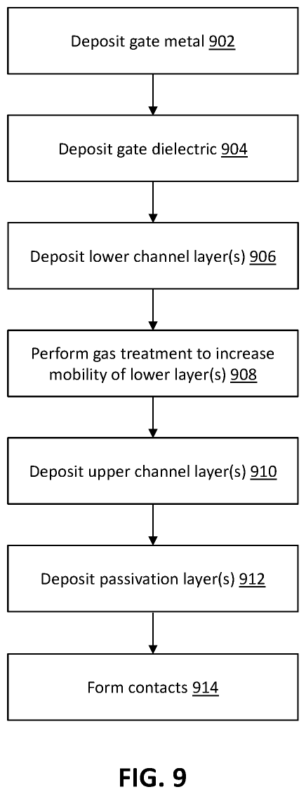

FIG. 9 is a flow diagram illustrating a process for fabricating a transistor with a multi-layered channel where the process includes a gas treatment on a lower layer of the channel, according to some embodiments of the present disclosure. At 902, a gate metal is deposited, as described with respect to the process 502 of FIG. 5. At 804, a gate dielectric may be deposited, as described with respect to the process 504 of FIG. 5.

At 906, one or more lower channel layers are deposited. For example, the channel materials 108 and 110 may be deposited as thin films to form the channel layers 145a and 145b. The lower channel material(s) may have any of the properties described with respect to FIGS. 1, 5, 6, and/or 7.

At 908, a gas treatment is performed on one or more of the lower channel layer(s) (e.g., the first channel layer 145a and/or second channel layer 145b) to enhance its mobility. For example, as described with respect to FIG. 1, a gas treatment may heal dangling bonds within a channel material or otherwise change configurations of the channel material at an atomic level. In some cases, a gas in the chamber during a gas treatment may be detectable in the channel material. For example, a lower channel layer may include nitrogen, sulfur, fluorine, hydrogen, or deuterium, which may suggest that a gas treatment was performed. In some embodiments, rather than, or in addition to, the gas treatment, a vacuum treatment, heat treatment, or other treatment that increases mobility of a semiconductor may be performed. In some embodiments, the processes 906 and 908 may be performed in parallel, e.g., the gas may be introduced during deposition of one or more lower channel layer(s).

At 910, one or more upper channel layers are deposited. For example, the channel material 112 may deposited as a thin film to form the channel layer 145c. The upper channel material(s) may have any of the properties described with respect to FIGS. 1, 5, 6, and/or 7. In some embodiments, the upper channel material is the same as the lower channel material, but the gas treatment is not performed, or a different treatment that increases stability for the upper layer is performed.

At 912, one or more passivation layers are deposited, as described with respect to the process 510 of FIG. 5. At 912, source and drain contacts are formed over the transistor, as described with respect to the process 512 of FIG. 5.

Additional Transistor Arrangements with Multi-Layer Channels

FIGS. 1-4 each illustrated a transistor with channel region on top of a gate, and contacts on top of the channel region. In other embodiments, a transistor with a layered channel material may have a different arrangement of the contacts and gates. For example, the source and drain contacts may be at the bottom or back-side of the transistor, while the gate is at the top or front-side of the transistor. Furthermore, three-dimensional transistor architectures, such as FinFETs, nanoribbon transistors, or nanowire transistors, may include layered channel materials.

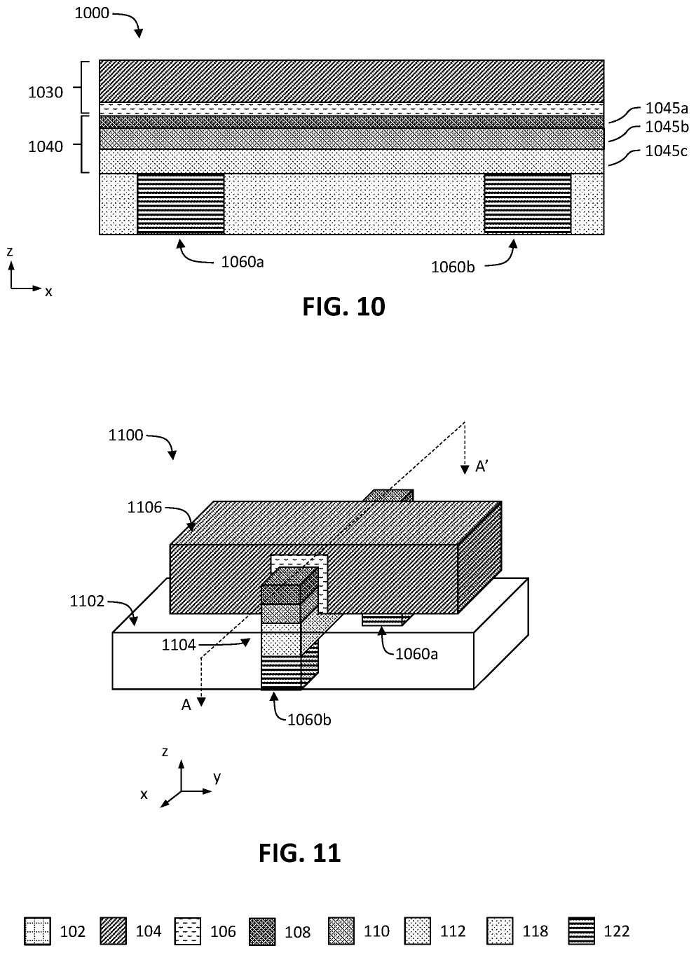

FIG. 10 is a cross-section of a transistor 1000 with a front-side gate and back-side source and drain contacts that may include a multi-layered channel, according to some embodiments of the present disclosure. In this example, two contacts 1060a and 1060b, which include the second contact material 122, are along the backside of the transistor 1000. A channel region 1040 is coupled to the contacts 1060, and a gate stack 1030 is coupled to the channel region 1040. In the orientation of FIG. 10, the channel region 1040 is on top of or over the contacts 1060, and the gate stack 1030 is on top of or over the channel region 1040. However, the contacts 1060 may also be considered over the channel region 1040, and the channel region 1040 may be considered over the gate stack 1030, e.g., by flipping orientation of the device.

The channel region 1040 includes a first channel layer 1045a that includes the first channel material 108. The first channel layer 1045a is nearest to the gate stack 1030, and is directly below the gate dielectric 106. The first channel layer 1045a may be considered a first layer of the channel region 1040 over the gate stack 1030. The channel region 1040 includes a second channel layer 1045b that includes the second channel material 110. The second channel layer 1045b is between the first channel layer 1045a and a third channel layer 1045c. The third channel layer 1045c may be considered over the second channel layer 1045b. The third channel layer 1045c is the farthest channel layer from the gate stack 1030. As with the transistors of FIGS. 1-4, the higher-mobility channel materials, e.g., the first channel material 108, are nearest to the gate electrode 104, and the lower-mobility channel materials, e.g., the third channel material 112, are farthest from the gate electrode 104.

FIG. 11 is a perspective view of an example transistor implemented as a FinFET that may include a multi-layered fin-shaped channel, according to some embodiments of the present disclosure. In some embodiments, the transistor 1000 is a thin-film, planar transistor. In other embodiments, the transistor 1000 has a three-dimensional, non-planar architecture, such as a FinFET. In this case, the cross-section in FIG. 10 may represent the cross-section through the plane AA′ in FIG. 11.

FinFETs generally refer to transistors having a non-planar architecture where a fin, formed of one or more semiconductor materials, extends away from a base (where the term “base” refers to any suitable support structure on which a transistor may be built, e.g., a substrate). A portion of the fin that is closest to the base may be enclosed by an insulator material. Such an insulator material, typically an oxide, is commonly referred to as a “shallow trench isolation” (STI), and the portion of the fin enclosed by the STI is typically referred to as a “subfin portion” or simply a “subfin.” A gate stack that includes at least a layer of a gate electrode material and, optionally, a layer of a gate dielectric may be provided over the top and sides of the remaining upper portion of the fin (i.e., the portion above and not enclosed by the STI), thus wrapping around the upper-most portion of the fin. The portion of the fin over which the gate stack wraps around is typically referred to as a “channel portion” of the fin because this is where, during operation of the transistor, a conductive channel forms, and is a part of an active region of the fin. Two S/D regions are provided on the opposite sides of the gate stack, forming a source and a drain terminal of a transistor. FinFETs may be implemented as “tri-gate transistors,” where the name “tri-gate” originates from the fact that, in use, such transistors may form conducting channels on three “sides” of the fin. FinFETs potentially improve performance relative to single-gate transistors and double-gate transistors.

Turning specifically to FIG. 11, the transistor 1100 illustrate the support structure 1102, a fin-shaped channel region 1104, and a gate 1106 wrapping around the fin-shaped channel region 1104. The support structure 1102 may be a low-k or high-k dielectric including, but not limited to, any of the dielectric materials described above. The contacts 1060a and 1060b are under the fin-shaped channel region 1104, on either side of the fin-shaped channel region 1104. The support structure 1102 is shown in outline to illustrate the contacts 1060a and 1060b, which may be embedded in the support structure 1102.

As shown in FIG. 11, the fin-shaped channel region 1104 may extend away from the support structure 1102 and may be substantially perpendicular to the support structure 1102. The fin-shaped channel region 1104 includes the three channel materials 108, 110, and 112, which are arranged in a layered stack, as described with respect to FIG. 10. In this example, a portion of the third channel material 112 extends into the support structure 1102. For example, the lower portion of the third channel material 112 may be the subfin described above. The upper portion of the third channel material 112, as well as the second channel material 110 and first channel material 108, are surrounded on their sides by the gate 1106. In other embodiments, a full layer, or multiple layers, of channel material may be below the gate 1106, e.g., in the subfin portion of the fin-shaped channel region 1104. In other embodiments, the fin-shaped channel region 1104 may not include a subfin.

The gate stack (i.e., the gate dielectric 106 and gate electrode 104) may wrap around the upper portion of the fin-shaped channel region 1104 (the portion above the support structure 1102), as shown in FIG. 11. In particular, the gate dielectric 106 (if used) may wrap around the upper-most portion of the fin-shaped channel region 1104, and the gate electrode 104 may wrap around the gate dielectric 106.

In some embodiments, the FinFET 1100 may have a gate length, GL, (i.e. a distance between the contacts 1060a and 1060b), a dimension measured along the fin-shaped channel region 1104 in the direction of the x-axis of the example reference coordinate system x-y-z shown in FIG. 11, which may, in some embodiments, be between about 5 and 40 nanometers, including all values and ranges therein (e.g. between about 22 and 35 nanometers, or between about 20 and 30 nanometers). The fin-shaped channel region 1104 may have a thickness, a dimension measured in the direction of the y-axis of the reference coordinate system x-y-z shown in FIG. 11, that may, in some embodiments, be between about 5 and 30 nanometers, including all values and ranges therein (e.g. between about 7 and 20 nanometers, or between about 10 and 15 nanometers). The fin-shaped channel region 1104 may have a height, a dimension measured in the direction of the z-axis of the reference coordinate system x-y-z shown in FIG. 11, which may, in some embodiments, be between about 30 and 350 nanometers, including all values and ranges therein (e.g. between about 30 and 200 nanometers, between about 75 and 250 nanometers, or between about 150 and 300 nanometers).

Although the fin-shaped channel region 1104 illustrated in FIG. 11 is shown as having a rectangular cross-section in a y-z plane of the reference coordinate system shown, the fin-shaped channel region 1104 may instead have a cross-section that is rounded or sloped at the “top” of the fin-shaped channel region 1104, and the gate stack may conform to this rounded or sloped shape. In use, the FinFET 1100 may form conducting channels on three “sides” of the fin-shaped channel region 1104, potentially improving performance relative to single-gate transistors (which may form conducting channels on one “side” of a channel material or substrate) and double-gate transistors (which may form conducting channels on two “sides” of a channel material or substrate).

### Example Devices

The circuit devices with transistors with layered channel material disclosed herein may be included in any suitable electronic device. FIGS. 12-15 illustrate various examples of apparatuses that may include the one or more transistors disclosed herein, which may have been fabricated using the processes disclosed herein.

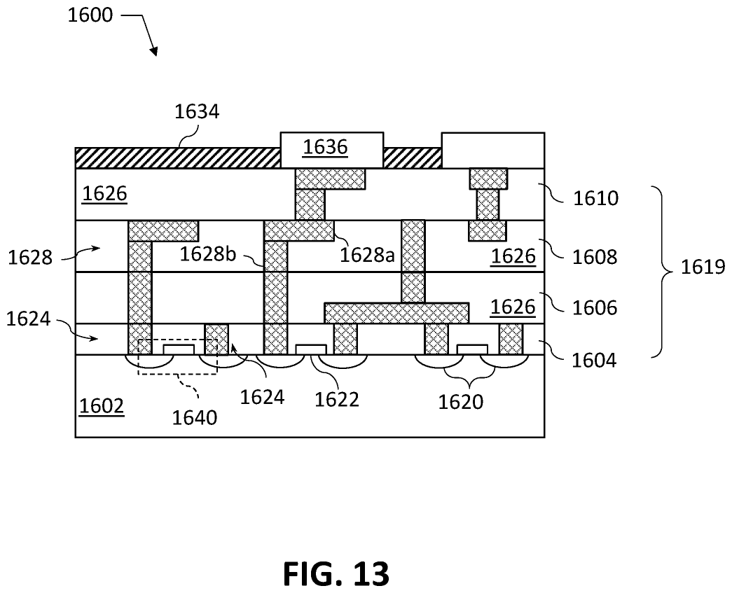

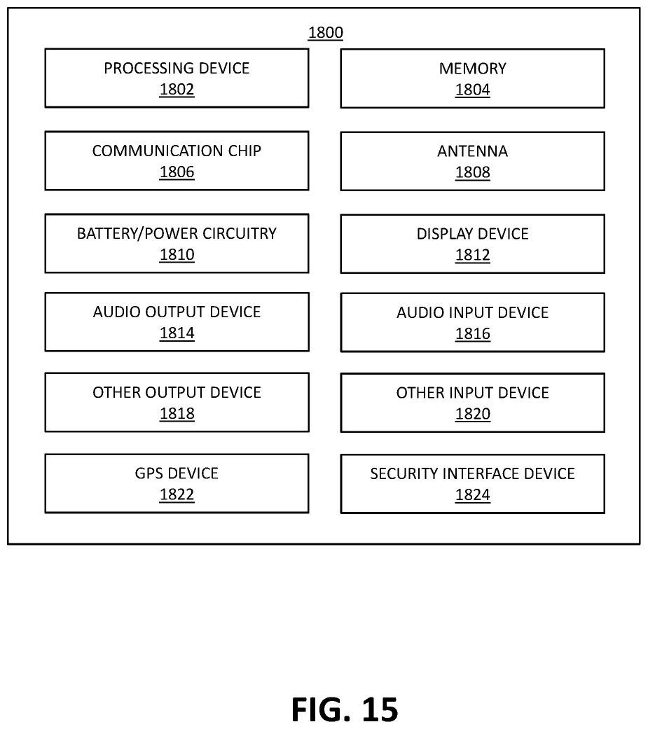

FIGS. 12A and 12B are top views of a wafer and dies that include one or more IC structures including one or more transistors with layered channel materials in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 2-14, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 13, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 15) or other logic that is configured to store information in the memory devices or execute instructions stored in the memory array.

FIG. 13 is a cross-sectional side view of an IC device 1600 that may include one or more transistors with layered channel materials in accordance with any of the embodiments disclosed herein. The IC device 1600 may be formed on a substrate 1602 (e.g., the wafer 1500 of FIG. 12A) and may be included in a die (e.g., the die 1502 of FIG. 12B). The substrate 1602 may be any substrate as described herein. The substrate 1602 may be part of a singulated die (e.g., the dies 1502 of FIG. 12B) or a wafer (e.g., the wafer 1500 of FIG. 12A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 13 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more transistors with layered channel materials at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 13 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 13). Although a particular number of interconnect layers 1606-1610 is depicted in FIG. 13, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 13. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 13. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

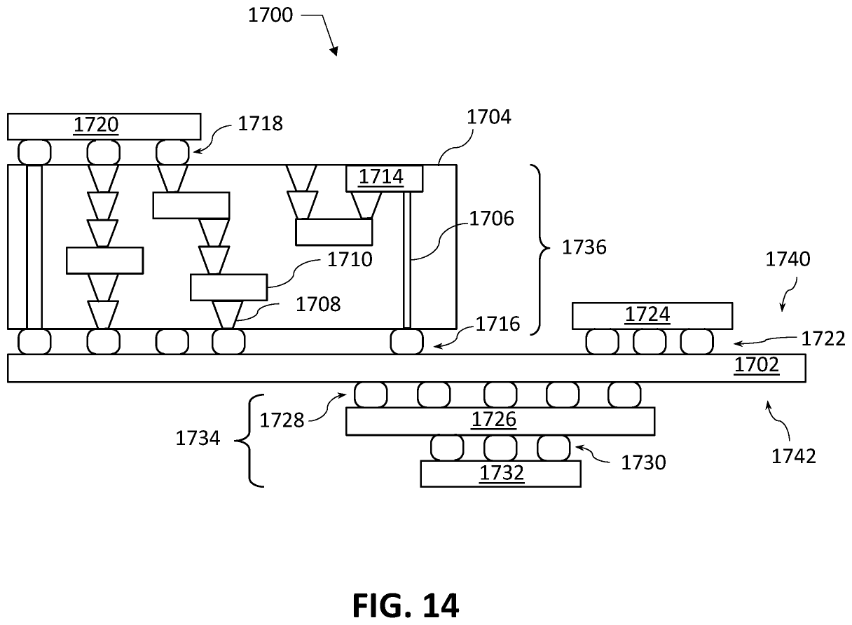

FIG. 14 is a cross-sectional side view of an IC device assembly 1700 that may include components having or being associated with (e.g., being electrically connected by means of) one or more transistors with layered channel materials in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 14 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 14), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 14, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 12B), an IC device (e.g., the IC device 1600 of FIG. 13), or any other suitable component. In some embodiments, the IC package 1720 may include one or more transistors with layered channel materials, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 14, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 14 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 15 is a block diagram of an example computing device 1800 that may include one or more transistors with layered channel materials in accordance with any of the embodiments disclosed herein. For example, any suitable ones of the components of the computing device 1800 may include a die (e.g., the die 1502 (FIG. 12B)) having one or more transistors with layered channel materials. Any one or more of the components of the computing device 1800 may include, or be included in, an IC device 1600 (FIG. 13). Any one or more of the components of the computing device 1800 may include, or be included in, an IC device assembly 1700 (FIG. 14).

A number of components are illustrated in FIG. 15 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 15, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled. In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random-access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above). The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### Select Examples

The following paragraphs provide various examples of the embodiments disclosed herein.

Example A1 provides an IC device that includes a conductive layer; and a channel region that includes a first channel layer, the first channel layer including a metal, where the metal is one of indium, copper, cobalt, and tin; and a second channel layer, where the first channel layer is between the conductive layer and the second channel layer, and the second channel layer has a lower concentration of the metal than the first channel layer.

Example A2 provides the IC device of example A1, where the first channel layer and the second channel layer further include oxygen.

Example A3 provides the IC device of example A1 or A2, where the second channel layer includes less than 0.01% of the metal by weight.

Example A4 provides the IC device of any preceding example, where the channel region further includes a third channel layer, where the second channel layer is between the first channel layer and the third channel layer, and the third channel layer has a lower concentration of the metal than the first channel layer.

Example A5 provides the IC device of example A4, where the third channel layer has a lower concentration of the metal than the second channel layer.

Example A6 provides the IC device of any preceding example, further including a third channel layer between the first channel layer and the second channel layer.

Example A7 provides the IC device of any preceding example, where the metal is indium.

Example A8 provides the IC device of any of examples A1-A6, where the metal is copper.

Example A9 provides the IC device of any of examples A1-A6, where the metal is tin.

Example A10 provides the IC device of any of examples A1-A6, where the metal is cobalt.

Example A11 provides the IC device of any preceding example, further including a first passivation layer over the channel region; and a second passivation layer over the first passivation layer.

Example A12 provides the IC device of any preceding example, where the first channel layer has a thickness of less than 20 nanometers.

Example A13 provides the IC device of any preceding example, where the second channel layer has a thickness of less than 20 nanometers.

Example A14 provides the IC device of example A12 or A13, where the first channel layer or the second channel layer is a monolayer.

Example A15 provides the IC device of any preceding example, further including a first contact and a second contact, each of the first contact and the second contact extending into the channel region.

Example A16 provides the IC device of example A15, where the first contact extends through the second channel layer and partially into the first channel layer.

Example A17 provides the IC device of example A15, where the first contact extends into the second channel layer, and does not extend into the first channel layer.

Example A18 provides the IC device of example A17, where the first contact extends partially into the second channel layer.

Example A19 provides the IC device of any of examples A15-A18, where the first contact includes a liner material and a core material, the core material having higher conductivity than the liner material.

Example A20 provides the IC device of any preceding example, further including a sealing layer over the channel region.

Example A21 provides the IC device of example A20, where the sealing layer includes at least one of aluminum, silicon, and yttrium.

Example A22 provides the IC device of any preceding example, where the second channel layer includes a nonmetal, and the second channel layer has a higher concentration of the nonmetal than the first channel layer.

Example A23 provides the IC device of example A22, where the nonmetal includes one of oxygen, nitrogen, sulfur, phosphorus, selenium, hydrogen, and deuterium.

Example A24 provides the IC device of any preceding example, where the second channel includes a second metal, where the second metal, when combined with oxygen or nitrogen, forms an insulator.

Example A25 provides the IC device of example A24, where the second channel includes a second metal, where the second metal includes at least one of aluminum, hafnium, tungsten, magnesium, and gallium.

Example B1 provides an IC device that includes a metal layer; a dielectric layer over the metal layer; a first semiconductor layer over the dielectric layer, the first semiconductor layer including a first semiconductor material; and a second semiconductor layer over the first semiconductor layer, the second semiconductor layer including a second semiconductor material and a nonmetal, the second semiconductor layer having a higher concentration of the nonmetal than the first semiconductor layer.

Example B2 provides the IC device of example B1, where the nonmetal is nitrogen.

Example B3 provides the IC device of example B1, where the nonmetal is oxygen.

Example B4 provides the IC device of example B1, where the nonmetal is one of sulfur, selenium, and phosphorus.

Example B5 provides the IC device of example B1, where the nonmetal is one of hydrogen or deuterium.

Example B6 provides the IC device of any of examples B1-B5, where the second semiconductor layer has a higher bandgap than the first semiconductor layer.

Example B7 provides the IC device of any of examples B1-B6, where the second semiconductor layer has a lower defect rate than the first semiconductor layer.

Example B8 provides the IC device of any of examples B1-B7, where the first semiconductor layer includes one of indium, copper, cobalt, and tin.

Example B9 provides the IC device of example B8, where the first semiconductor layer further includes oxygen.

Example B10 provides the IC device of any of examples B1-B9, further including a dielectric layer over the second semiconductor layer.

Example B11 provides the IC device of example B10, where the dielectric layer is a first passivation layer, and the IC device further includes a second passivation layer over the first passivation layer.

Example B12 provides the IC device of example B10 or B11, where the dielectric layer is a sealing layer over the second semiconductor layer.

Example B13 provides the IC device of any of examples B10-B12, where the dielectric layer includes at least one of aluminum, silicon, and yttrium.

Example B14 provides the IC device of any of examples B1-B13, where the first semiconductor layer has a thickness of less than 20 nanometers.

Example B15 provides the IC device of any of examples B1-B14, where the semiconductor channel layer has a thickness of less than 20 nanometers.

Example B16 provides the IC device of example B14 or B15, where the first semiconductor layer or the second semiconductor layer is a monolayer.

Example B17 provides the IC device of any of examples B1-B16, further including a third semiconductor layer between the second semiconductor layer and the first semiconductor layer.

Example C1 provides a transistor that includes a first layer including a conductor; a second layer over the first layer, the second layer including oxygen and a first metal; and a third layer over the second layer, the third semiconductor layer including oxygen, the first metal, and a second metal, where the second metal, when combined with oxygen or nitrogen, forms an insulator.

Example C2 provides the transistor of example C1, where the third layer further includes nitrogen.

Example C3 provides the transistor of example C1 or C2, where the second metal is aluminum.

Example C4 provides the transistor of example C1, where the second metal is hafnium, and the second metal, when combined with oxygen, forms hafnium oxide.

Example C5 provides the transistor of any of examples C1-C4, where the third layer has a higher bandgap than the second layer.

Example C6 provides the transistor of any of examples C1-C5, further including a fourth layer between the first layer and the second layer, the fourth layer including an insulator.

Example C7 provides the transistor of any of examples C1-C6, where the second layer includes one of indium, copper, cobalt, and tin.

Example C8 provides the transistor of example C7, where the second layer further includes oxygen.

Example C9 provides the transistor of any of examples C1-C8, where the second layer further includes the second metal, where a concentration of the second metal in the second layer is less than a concentration of the second metal in the third layer.

Example C10 provides the transistor of any of examples C1-C9, further including a fourth layer between the second layer and the third layer, where the fourth layer has a lower concentration of the second metal than the third layer.

Example C11 provides the transistor of any of examples C1-C10, further including a first contact and a second contact, each of the first contact and the second contact extending into the third layer.

Example C12 provides the transistor of example C11, where at least one of the first contact and the second contact extend into the second layer.

Example D1 provides a transistor that includes a first layer including a conductor; a second layer over the first layer, the second layer including a semiconductor material with a first carrier type; and a third layer over the second layer, the third layer including a second carrier type, where the first carrier type and the second carrier type are opposite carrier types.

Example D2 provides the transistor of example D1, where the first carrier type is electrons, and the second carrier type is holes.

Example D3 provides the transistor of example D1, where the first carrier type is holes, and the second carrier type is electrons.

Example D4 provides the transistor of any of examples D1-D3, the transistor including a channel region, the channel region including the second layer and the third layer.

Example D5 provides the transistor of any of examples D1-D3, where the second layer is a channel layer, and the third layer is a passivation layer.

Example D6 provides the transistor of any of examples D1-D5, where the second layer includes a metal and oxygen.

Example D7 provides the transistor of examples D6, where the third layer includes the metal and oxygen.

Example D8 provides the transistor of examples D7, where the second layer and the third layer have different concentrations of oxygen.

Example D9 provides the transistor of any of examples D6-D8, where the metal is tin.

Example D10 provides the transistor of any of examples D6-D8, where the metal is copper.

Example D11 provides the transistor of any of examples D1-D10, further including a fourth layer between the second layer and the third layer, where the fourth layer includes the first carrier type.

Example D12 provides the transistor of example D11, where the fourth layer has a lower concentration of carriers of the first carrier type than the second layer.

Example D13 provides the transistor of any of examples D1-D12, where the second layer has a thickness of less than 20 nanometers.

Example D14 provides the transistor of any of examples D1-D13, where the third layer has a thickness of less than 20 nanometers.

Example D15 provides the transistor of example D13 or D14, where the second layer or the third layer is a monolayer.

Example D16 provides the transistor of any of examples D1-D15, further including a first contact and a second contact, each of the first contact and the second contact extending into the third layer.

Example D17 provides the transistor of example D16, where the first contact extends through the third layer and partially into the second layer.

Example D18 provides the transistor of example D16 or D17, where the first contact includes a liner material and a core material, the core material having higher conductivity than the liner material.

Example D19 provides the transistor of any of examples D1-D19, further including a sealing layer over the third layer.

Example D20 provides the transistor of example D19, where the sealing layer includes at least one of aluminum, silicon, and yttrium.

Example E1 provides an IC device that includes a conductive layer; a channel region including a first channel layer and a second channel layer, the first channel layer closer to the conductive layer than the second channel layer, and the first channel layer having a higher carrier mobility than the second channel layer; and a pair of contacts coupled to the channel region.

Example E2 provides the IC device of example E1, further including a dielectric layer over the channel region and between the pair of contacts.

Example E3 provides the IC device of example E2, where the dielectric layer is a passivation layer.

Example E4 provides the IC device of example E2 or E3, where the dielectric layer includes at least one of nitrogen and oxygen; and a metal, where the metal, when combined with oxygen or nitrogen, forms an insulator.

Example E5 provides the IC device of any of examples E2-E4, where the dielectric layer is a first dielectric layer, the IC device further including a second dielectric layer over the first dielectric layer.

Example E6 provides the IC device of example E5, where the second dielectric layer is a hermetic seal over the channel region.

Example E7 provides the IC device of any of examples E1-E6, where each of the pair of contacts includes a liner material and a core material, the core material having higher conductivity than the liner material.

Example E8 provides the IC device of any of examples E1-E7, where the channel region has a fin shape.

Example E9 provides the IC device of any of examples E1-E8, where the contacts extend at least partially into the channel region.

Example E10 provides the IC device of any of examples E1-E9, where the contacts are on a back side of the IC device, and the conductive layer is on a front side of the IC device.

Example F1 provides a method that includes depositing a conductive material; forming a first channel layer over the conductive material; forming a second channel layer over the first channel layer, the second channel layer having a different composition from the first channel layer, the first channel layer and the second channel layer forming a channel region; and forming a pair of contacts to the channel region.

Example F2 provides the method of example F1, where forming the first channel layer includes depositing a semiconductor material; and performing a gas treatment of the semiconductor material to increase mobility of the semiconductor material.

Example F3 provides the method of example F2, where the gas treatment adds at least one of nitrogen, sulfur, fluorine, hydrogen, or deuterium to the semiconductor material.

Example F4 provides the method of example F2 or F3, where the gas treatment reduces a defect level of the first channel layer.

Example F5 provides the method of any of examples F1-F4, where forming the second channel layer includes depositing a semiconductor material; and performing a gas treatment of the semiconductor material to increase stability of the semiconductor material.

Example F6 provides the method of example F5, where the gas treatment adds an insulating material to the semiconductor material.

Example F7 provides the method of any of examples F1-F6, where forming the second channel layer includes a forming, in the second channel layer, a mixture of a semiconductor and an insulator.

Example F8 provides the method of example F7, where the insulator includes a metal oxide or a metal nitride.

Example F9 provides the method of example F7 or F8, where the insulator includes at least one of aluminum and hafnium.

Example F10 provides the method of any of examples F7-F9, where the insulator includes at least one of tungsten, magnesium, and gallium.

Example F11 provides the method of any of examples F1-F10, where the first channel layer includes one of indium, copper, cobalt, and tin.

Example F12 provides the method of example F11, where the first channel layer further includes oxygen.

Example F13 provides the method of any of examples F1-F12, where the first channel layer includes a first carrier type, and the second channel layer includes an opposite carrier type.

Example F14 provides the method of example F13, where the first channel layer includes a different concentration of oxygen than the first channel layer.

Example F15 provides the method of any of examples F1-F14, where forming the pair of contacts to the channel region includes forming a liner including a first contact material; and forming a core including a second contact material.

Example F16 provides the method of example F15, further including performing a gas treatment of the liner prior to forming the core.

Example F17 provides the method of example F15 or F16, where the first contact material includes a semiconductor material and at least one of indium, tin, cobalt, or copper.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. An integrated circuit (IC) device comprising:
a conductive layer; and
a channel region comprising:
a first channel layer comprising a metal, wherein the metal is one of indium, copper, cobalt, and tin, and
a second channel layer, wherein the first channel layer is between the conductive layer and the second channel layer, and the second channel layer has a lower concentration of the metal than the first channel layer.

2. The IC device of claim 1, wherein the first channel layer and the second channel layer further comprise oxygen.

3. The IC device of claim 1, wherein the second channel layer comprises less than 0.01% of the metal by weight.

4. The IC device of claim 1, wherein the channel region further comprises:
a third channel layer, wherein the second channel layer is between the first channel layer and the third channel layer, and the third channel layer has a lower concentration of the metal than the first channel layer.

5. The IC device of claim 1, further comprising:
a first passivation layer over the channel region; and
a second passivation layer over the first passivation layer.

6. The IC device of claim 1, wherein the first channel layer has a thickness of less than 20 nanometers.

7. The IC device of claim 1, wherein the second channel layer has a thickness of less than 20 nanometers.

8. The IC device of claim 1, wherein the first channel layer or the second channel layer is a monolayer.

9. The IC device of claim 1, wherein the second channel layer comprises a nonmetal, and the second channel layer has a higher concentration of the nonmetal than the first channel layer.

10. The IC device of claim 9, wherein the nonmetal comprises one of oxygen, nitrogen, sulfur, phosphorus, selenium, hydrogen, and deuterium.

11. A transistor comprising:
a first layer comprising a conductor;
a second layer over the first layer, the second layer comprising a semiconductor material with a first carrier type; and
a third layer over the second layer, the third layer comprising a second carrier type, wherein the first carrier type and the second carrier type are opposite carrier types.

12. The transistor of claim 11, wherein the second layer comprises a metal and oxygen, and the third layer comprises the metal and oxygen.

13. The transistor of claim 12, wherein the second layer and the third layer have different concentrations of oxygen.

14. The transistor of claim 12, wherein the metal is tin or copper.

15. The transistor of claim 11, further comprising a fourth layer between the second layer and the third layer, wherein the fourth layer comprises the first carrier type.

16. The transistor of claim 15, wherein the fourth layer has a lower concentration of carriers of the first carrier type than the second layer.

17. The transistor of claim 11, further comprising a first contact and a second contact, each of the first contact and the second contact extending into the third layer.

18. An integrated circuit (IC) device comprising:
a conductive layer;
a channel region over the conductive layer, the channel region comprising a first channel layer and a second channel layer, the first channel layer closer to the conductive layer than the second channel layer, and the first channel layer having a higher carrier mobility than the second channel layer; and
a pair of contacts extending at least partially into the channel region.

19. The IC device of claim 18, further comprising a dielectric layer over the channel region and between the pair of contacts.

20. The IC device of claim 18, wherein each of the pair of contacts comprises a liner material and a core material, the core material having higher conductivity than the liner material.
